(19) United States
(12) Patent Application Publication
(10) Pub. No.: US 2012/0212305 A1
(43) Pub. Date: Aug. 23, 2012

(54) FILTER CIRCUIT AND METHOD OF TUNING FILTER CIRCUIT

(75) Inventor: Steven K. Shafer, Chittenango, NY (US)

(73) Assignee: JOHN MEZZALINGUA ASSOCIATES, INC., East Syracuse, NY (US)

(21) Appl. No.: 13/031,559

(22) Filed: Feb. 21, 2011

(51) Int. Cl. H03H 7/00

(52) U.S. Cl. 333/174; 333/185

(57) ABSTRACT

A filter circuit device is disclosed having a printed circuit board with first and second opposed major surfaces, an input, and an output. A first signal path is disposed on the printed circuit board extending from the input toward the output. A resonant circuit element is coupled to the first signal path and configured as a filter circuit. The resonant circuit element comprises a coil-wound tunable inductor element in serial electrical communication with an etched inductor element. The coil-wound tunable inductor element and the etched inductor element are in parallel electrical communication with a capacitor. A second signal path is further disposed on the printed circuit board extending from a first node on the first signal path. A shunt element is disposed on the second signal path that comprises a conductive grounding path terminated to electrical ground. An inductor and a capacitor in series electrical communication are coupled to the grounding path. In one embodiment, the coil-wound inductor element may be tuned to adjust a resonant frequency of the filter circuit.

### FIELD OF THE INVENTION

This disclosure relates generally to the field of filter circuits of the type used in cable television systems and, more specifically, to a filter circuit having an improved tunable inductor element.

### BACKGROUND OF THE INVENTION

In a typical cable television (CATV) network, a head-end facility generally broadcasts a variety of programs in a number of respective frequency channels. At the user end of the network, users selectively tune their television units and other media devices to particular frequency channels to receive particular programs. In many such networks, particular ranges of channels are dedicated to particular subscription contracts or tentative pay-per-view arrangements. For example, premium programming selections, for which extra payments are required, may be exclusively provided on dedicated ranges of frequency channels. Content selection broadcast on a forward path bandwidth of the CATV system may include broadcast television channels, video on demand services, internet data, home security services, and voice over internet (VOIP) services. Forward path bandwidth includes frequencies typically ranging from 50-1,002 megahertz (MHz).

The typical CATV system is a two-way communication system. The forward path bandwidth carries signals from the head end to the user and a return path bandwidth carries signals from the user to the head end. Return path bandwidth may include data related to video on demand services, such as video requests and billing authorization; internet uploads, such as photo albums or user account information; security monitoring; or other services predicated on signals or data emanating from a subscriber's home. Return path bandwidth frequencies typically range from 5-49 MHz.

A variety of electronic filters are used by CATV operators to segregate or enhance signals. For example, a low pass filter may be used to pass the return path signals from the user-end to the head-end, while attenuating forward path frequencies. Conversely, a high pass filter may be used to pass the forward path signals from the head end to the user end, while attenuating return path frequencies. Another type of filter used to attenuate transmission of signals in a specified frequency range is a bandstop filter. Yet another type of filter is a diplex circuit, or diplexer, which separates or combines RF signals.

It is desirable that the filters be as compact as possible commensurate with quality performance of their intended function. It is also desirable, of course, that the filters be as inexpensive as possible, again while maintaining high performance criteria.

### SUMMARY OF THE INVENTION

A filter circuit device is provided having a printed circuit board with first and second opposed major surfaces, an input, and an output. A first signal path is disposed on the printed circuit board extending from the input toward the output. A resonant circuit element is coupled to the first signal path and configured as a filter circuit. The resonant circuit element comprises a coil-wound tunable inductor element in serial electrical communication with an etched inductor element. The coil-wound tunable inductor element and the etched inductor element are in parallel electrical communication with a capacitor. A second signal path is further disposed on the printed circuit board extending from a first node on the first signal path. A shunt element is disposed on the second signal path that comprises a conductive grounding path terminated to electrical ground. An inductor and a capacitor in series electrical communication are coupled to the grounding path. In one embodiment, the coil-wound inductor element may be tuned to adjust a resonant frequency of the filter circuit.

In one aspect of the invention, the shunt element further includes a coil-wound tunable inductor element in serial electrical communication with an etched inductor element that are in serial electrical communication with the capacitor.

In one aspect of the invention, the first signal path is a low pass filter circuit, and the first signal path further includes a shunt capacitor coupled to electrical ground.

In one aspect of the invention, the filter circuit device further includes a plurality of resonant circuit elements and a plurality of shunt capacitors arranged and configured to pass an upstream bandwidth in the 5-50 MHz frequency range.

In another aspect of the invention, the filter circuit device further includes a second output connected to the printed circuit board, and the second signal path extends from the first node to the second output. The shunt element extends from the second signal path.

In one aspect of the invention, the filter circuit device further includes a plurality of shunt elements extending from the second signal path. The shunt elements are arranged in parallel electrical communication and separated from each other by capacitors coupled to the second signal path.

In one aspect of the invention, the plurality of shunt elements and capacitors form a high pass filter circuit arranged and configured to pass a downstream CATV bandwidth in the 54-1000 MHz frequency range and attenuate an upstream bandwidth in the 5-50 MHz frequency range.

In another aspect of the invention, the second major surface includes a solid ground plane and the coil-wound tunable inductor element includes a surface mount design.

In another aspect of the invention, a method for tuning a filter circuit is provided comprising the steps of providing a circuit board with an input, an output, and a signal path extending from the input toward the output. A shunt element is provided on a second signal path that extends from a first node on the first signal path. The shunt element comprises a capacitor coupled to ground. The method comprises the step of electrically coupling a resonant circuit element to the first signal path between the first node and the output, where the resonant circuit element comprises a tunable coil wound inductor element in serial electrical communication with an etched inductor element. The resonant circuit element further comprises a capacitor in parallel electrical communication with the coil-wound tunable inductor element and the etched inductor element. A resonant frequency of the filter circuit may be adjusted using the coil wound inductor element on the first signal path.

In a further aspect of the invention, the step of electrically coupling a resonant circuit element to the first signal path includes coupling a plurality of resonant circuit elements.

In another aspect of the invention, the filter circuit further includes a second output on the second signal path. The second signal path further includes a plurality of shunt elements including a coil-wound tunable inductor element, an etched inductor element, and a capacitor in serial electrical communication. The filter circuit further includes a capacitor disposed between the plurality of shunt elements, and the method further includes the step of adjusting a resonant frequency of the filter circuit using the coil wound inductor element on the second signal path.

In one aspect of the invention, the filter circuit is a band pass filter circuit, and the step of adjusting a resonant frequency on the first signal path includes tuning the coil wound inductor element to pass a downstream cable television bandwidth in the 54-1000 MHz frequency range while rejecting the upstream bandwidth in the 5-50 MHz frequency range.

In one aspect of the invention, the step of adjusting a resonant frequency on the second signal path includes tuning the coil wound inductor element to pass a downstream cable television bandwidth in the 5-50 MHz frequency range and rejecting bandwidth in the 54-1000 MHz frequency range.

### BRIEF DESCRIPTION OF THE DRAWINGS

The features described herein can be better understood with reference to the drawings described below. The drawings are not necessarily to scale, emphasis instead generally being placed upon illustrating the principles of the invention. In the drawings, like numerals are used to indicate like parts throughout the various views.

FIG. 1 is a circuit diagram, in schematic form, of a home networking filter according to an embodiment of the invention;

FIGS. 2A and 2B are top and bottom plan views, respectively, showing the physical positioning on opposite surfaces of a circuit board for the filter circuit shown schematically in FIG. 1;

FIG. 3 is a circuit diagram, in schematic form, of a diplexer filter according to an embodiment of the invention;

FIGS. 4A and 4B are top and bottom plan views, respectively, showing the physical positioning on opposite surfaces of a circuit board for the diplexer filter circuit shown schematically in FIG. 3; and

FIGS. 5A and 5B are top and bottom plan views, respectively, showing the physical positioning on opposite surfaces of a circuit board for another embodiment of the filter circuit shown schematically in FIG. 3.

### DETAILED DESCRIPTION OF THE INVENTION

Two exemplary electronic filter constructions for CATV systems include traditional minimum inductance filters and minimum inductance elliptic filters. Each type includes arrangements of inductors and capacitors, as will be discussed further below, to achieve desired pass band and filter band characteristics. Inductors generally fall into two categories: coil wound and etched. The surface-mount variety of inductor typically comprises a coil wound around a ferrite or ceramic core or, alternately, a coil wound air coil. The second category is the etched inductor, in which the inductor element is etched or metalized directly into the printed circuit board.

Each type of inductor has advantages and disadvantages, and the filter designer must balance these in selecting the appropriate configuration. For example, to achieve its desired performance, a coil wounded inductor may have a large form factor, meaning the inductor is large and bulky. It is not uncommon for the coil wound inductors in a higher-order elliptic Chebyshev low pass filter to occupy an area of about 2 inches by 0.75 inches (1.5 square inches) on a circuit board. The size and number of inductors cannot be reduced if performance specifications are to be met. One advantage of the coil wound inductor is that the individual resonance of each inductor may be adjusted to give precise performance and very accurate range.

Etched inductors are popular because they are very economical to manufacture. However, there exist several drawbacks. First, etched coil inductors may have a relatively large form factor, and therefore may not be suitable for all circuit boards. Second, since etched inductors are fixed into the substrate, they are not tunable. This inflexibility may be problematic in a mass-production environment because manufacturing tolerances and variables such as changes to the circuit board substrate may alter the resonating characteristics of the inductor arrangement. Third, etched inductors often require precision capacitors to maintain the filter specifications in production, which increases cost. Another problem is that etched inductor elements are open structures that generate magnetic and electrical fields, which travel through air and cross through conductive traces of adjacent inductor elements, thereby modifying their individual inductances. This coupling action modifies the performance of the resonator (tank) elements. Since the individual inductors cannot be tuned, achieving proper circuit response may be very difficult when more than two or three inductors make up a circuit. Thus, circuit designers are often faced with the choice of having large, bulky filter circuits with exacting performance, or miniature filter circuits that must allow for wide variances in manufacturing because they cannot be adjusted. Failure to account for the wide variances in the design stage may result in high scrap rates due to intrinsic manufacturing tolerances.

The choice between coil wound and etched inductors is further complicated by the advent of the home networking bandwidth transmitting on the same coaxial line as the CATV system. For example, a home network may be coupled to the cable television network via the same coaxial cable delivering the forward path and return path bandwidth of the CATV system. Often, the user data network is a home entertainment network providing multiple streams of high definition video and entertainment. Examples of home networking technologies include Ethernet, HomePlug, HPNA, and 802.11n. In another example, the home network may employ technology standards developed by the Multimedia over Coax Alliance (MoCA). The MoCA standards promote networking of personal data utilizing the existing coaxial cable that is wired throughout the user premises. MoCA technology provides the backbone for personal data networks of multiple wired and wireless products including voice, data, security, home heating/cooling, and video technologies. In such an arrangement, the cable drop from the cable system operator shares the coaxial line or network connection a MoCA-certified device such as a broadband router.

The home network may utilize an open spectrum bandwidth on the coaxial cable to transmit the personal data content, such as entertainment content. For example, a cable system operator may utilize a bandwidth of frequencies up to 1002 MHz, and a satellite system operator may utilize a bandwidth of frequencies up to 2450 MHz. In one particular example, the Multimedia over Coax Alliance specifies an open spectrum, or home network bandwidth, of 1125-1525 MHz. The cable and satellite system operators comply with this specification by not transmitting any data in the open spectrum bandwidth. Therefore, a home network utilizing the open spectrum bandwidth does not interfere with any of the bandwidth being utilized by the cable television services provider or a satellite services provider.

It is desirable not to transmit the home network bandwidth along the return path to the CATV system. Accordingly, point-of-entry filters have been developed to attenuate the home network frequencies while passing the CATV frequencies. In one example, the point-of-entry filter attenuates or rejects frequencies in the MoCA spectrum, and is herein referred to as a MoCA filter. The MoCA filter is an unusual low pass filter in that the pass band is very broad-namely, the CATV bandwidth. Designing a traditional minimum inductance filter or a minimum inductance elliptic filter circuit that meets these criteria has proved challenging, and is the subject of U.S. patent application Ser. No. 12/501,041 entitled “FILTER CIRCUIT”, which is incorporated herein by reference in its entirety. In addition to the challenges circuit board designers faced regarding selection of inductors for the MoCA filter, the designers concurrently strove to minimize the physical size of the circuit board layout.

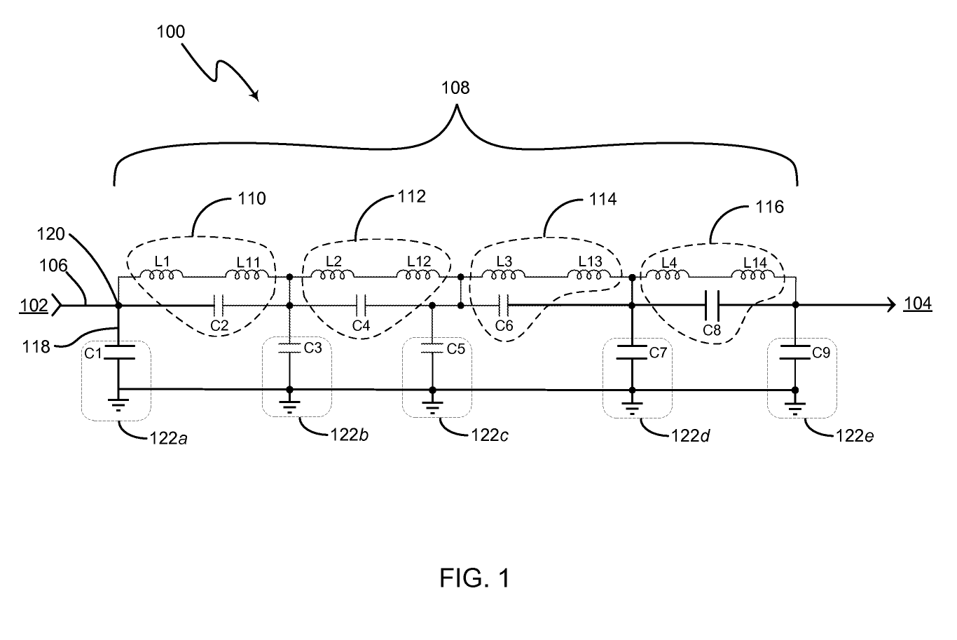

Referring to FIG. 1, the circuit diagram represents the components of an exemplary home networking filter circuit 100, and the electrical connections among the components. The filter circuit 100 includes an input 102 and an output 104. In the illustrated example, a signal path 106 is defined between the input 102 and the output 104 and is best characterized as a low pass circuit 108. In one example, the input 102 is connected to a supplier-side port within a drop system, such as a tap port. The output 104 may be adapted to receive unfiltered signals comprising the entire cable television bandwidth, home network bandwidth, noise, and any other signals present on the coaxial cable. Conversely, the input 102 may be connected to a user-side port and the output 104 may be connected to the supplier-side port. Further, the filter circuit 100 may be adapted to filter signals in both directions (e.g., bi-directional), so the physical location of the input 102 and output 104 may be arbitrary.

Transmission is understood to occur when an oscillating electrical signal is presented at the input 102 and, in response to the presented signal, a same-frequency oscillating electrical signal develops at the output 104. The signal developed at the output may be attenuated relative to the signal presented at the input 102 due to reflections from the filter circuit 100 back toward the source of the presented signal, signal losses along multiple shunt elements C1, C3, C5, C7, and C9 and general signal degradation due to resistive energy losses, for example.

The low pass circuit 108 may include multiple resonant circuit elements first resonant circuit element 110, 112, 114, and 116 which are in ordered series electrical communication with each other. Each particular resonant circuit element includes a particular capacitor (C) and at least two series-connected inductors (L) connected in parallel electrical communication with the capacitor. For example, the first resonant circuit element 110 includes the series-connected inductors L1 and L11 in parallel communication with the capacitor C2, the resonant circuit element 112 includes the series-connected inductors L2 and L12 in parallel communication with the capacitor C4, and so forth. The resonant circuit elements together with shunt capacitors C1, C3, C5, C7, and C9 form a minimum inductance elliptic function filter, in one example.

The filter circuit 100 includes a second signal path 118 extending from at least a first node 120 on the first signal path. A shunt element 122 disposed on the second signal path 118 includes a conductive grounding path terminated to electrical ground. In the illustrated embodiment, the shunt element 122 may include capacitor C1, or, as depicted in the illustrated embodiment, may further include a plurality of capacitors C3, C5, C7, and C9 coupled to the grounding path.

The low pass circuit 108 may be arranged and configured to pass the entire CATV bandwidth while attenuating home networking bandwidth, such as MoCA bandwidth. In one example, the low pass circuit 108 passes a bandwidth in the 5-1000 MHz frequency range while attenuating bandwidth in the 1125-1525 MHz frequency range.

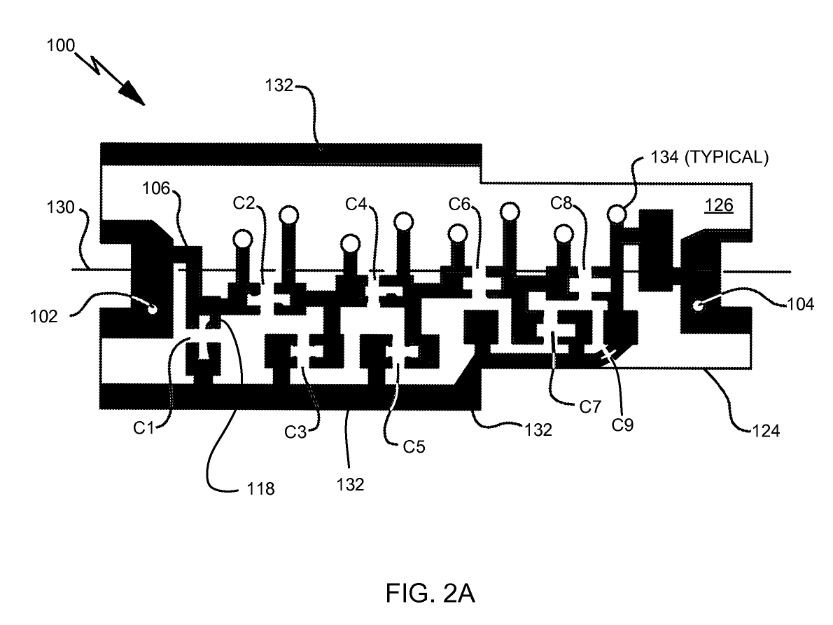

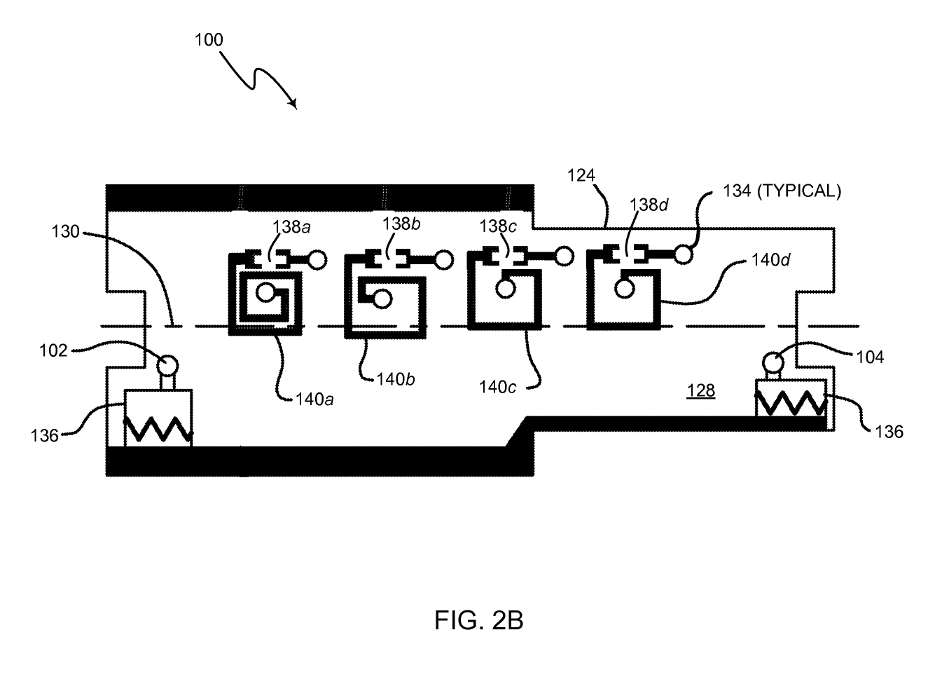

Referring to FIGS. 1, 2A, and 2B, shown is a physical layout of the components forming the filter circuit 100 according to one embodiment of the invention. The filter 100 includes a printed circuit board 124 having a first major surface 126 and a second major surface 128. The first major surface 126 is denoted as the top layer in FIG. 2A, and the second major surface 128 is denoted as the bottom layer in FIG. 2B. The input 102 and the output 104 are provided at opposing ends of the circuit board 124 and extend along a centerline 130. The first surface 126 includes a signal path 106 joining the input 102 to the output 104. In the illustrated example, the signal path 106 is printed on the circuit board 124 using metallization and/or an etching process.

The circuit board 124 may be formed from 0.8 millimeter FR-4 (woven glass and epoxy) with 1 ounce copper, double sided, but depending upon the dielectric requirements of the circuit, the substrate may be other materials such as FR-2 (phenolic cotton paper), FR-3 (cotton paper and epoxy), FR-6 (matte glass and polyester), CEM-1 (cotton paper and epoxy), CEM-5 (woven glass and polyester), aluminum, or ceramic. The circuit board 124 is not limited to rigid substrate materials. In one embodiment, the circuit 100 is disposed on flexible circuit board material.

The first surface 126 further includes a second signal path 118 disposed on the printed circuit board extending from the first node on the first signal path 106. In the illustrated example, the second signal path 118 is a grounding path 132, and a shunt element 122 is disposed on the grounding path. In one example, the shunt element 122 includes capacitor C1. In another example, such as that illustrated in FIG. 2A, the shunt element 122 includes a plurality of capacitors, namely C1, C3, C5, C7, and C9 coupled to the grounding path 132. In one example (not shown), the shunt element 122 and ground path 132 are in electrical communication with a coaxial cable connector body. The connector body, in turn, is in electrical communication with the outer conductive layer of a coaxial cable, which is in electrical communication with the ground block.

The first surface 126 further includes capacitor elements C2, C4, C6, and C8 as part of resonator elements 110, 112, 114, and 116. The capacitor elements C2, C4, C6, and C8 are arranged in parallel with inductor elements on the second major surface 128 (FIG. 2B) by conductive vias 134 that extend through the circuit board substrate.

In the disclosed embodiment, the capacitor elements C1-C9 are the surface-mount variety; however, metalized or etched capacitors would function adequately and may even have benefits over the surface mount variety.

Turning now to FIG. 2B, the second surface 128 of the circuit board 124 includes spark gap arrestors 136 to protect the filter circuit 100 from excessive voltage. The illustrated spark gap arrestors 136 include a gap distance of approximately 0.13 millimeters (mm) between the conductive portion of the signal path 106 and the grounding path 132. The second surface 128 further includes at least one resonant circuit element having a coil wound inductor element in serial electrical communication with an etched inductor element. In the disclosed embodiment, a plurality of resonant circuit elements 110, 112, 114, and 116 include coil wound inductor elements 138a-138d in serial electrical communication with etched inductor elements 140a- 140d. The inductor elements 138, 140 correspond to the inductor elements L1, L11, etc. depicted in FIG. 1, and are necessary to achieve the desired frequency response of the filter circuit 100. The combination of coil wound and etched inductor elements provide a small form factor and accurate tuning capability heretofore unrealized in a filter circuit.

The etched inductor element 140, because it is inexpensive to manufacture, may have an inductance value that is approximately 50% of the total inductance value required of the resonant circuit element. The coil wound inductor element 138 provides the remainder of the total inductance value and further provides the tuning capability that is lacking with the etched inductor element 140. Manufacturing tolerances and variables such as changes to the circuit board substrate may alter the resonating characteristics of the inductor arrangement. In one example, the manufacturing/material variability may alter the characteristic resonance by approximately 25%. In that case, the etched inductor element 140 may have an inductance value that is approximately 75% of the total inductance value required of the resonant circuit, with the coil wound inductor element 138 providing the remaining 25%. Accordingly, the form factor for the coil wound inductor element 138 will be relatively small as compared to a coil wound inductor element that was providing all of the inductance value for the resonant circuit element. In another example, the production variability may alter the resonating characteristics by approximately 10%. Then, the etched inductor element 140 may have an inductance value that is approximately 90% of the total inductance value required of the resonant circuit, with the coil wound inductor element 138 providing the remaining 10%.

In one example, the filter circuit 100 may be tuned prior to shipment from the manufacturing site. A work bench may be set up at the assembly line to determine the response of the filter circuit 100 and, using the coil-wound tunable inductor element, the signal response of the circuit may be adjusted with a high degree of precision to meet or exceed stringent circuit specifications.

In another embodiment, a tunable coil-wound inductor element in serial electrical communication with an etched inductor element may be utilized in a diplexer circuit, such as that disclosed for a conditioning circuit in U.S. patent application Ser. No. 12/576,612 entitled “TOTAL BANDWITH CONDITIONING DEVICE”, which is incorporated herein by reference in its entirety. In that design, a user-side diplexer circuit and a supplier-side diplexer circuit function as a combination of a splitter, a high-pass filter, and a low-pass filter. Each of the high-pass filters are arranged and configured in one example to pass downstream bandwidth in the 54 MHz to 1000 MHz frequency range, and each of the low-pass filters are arranged and configured to pass upstream bandwidth in the 5-50 MHz frequency range.

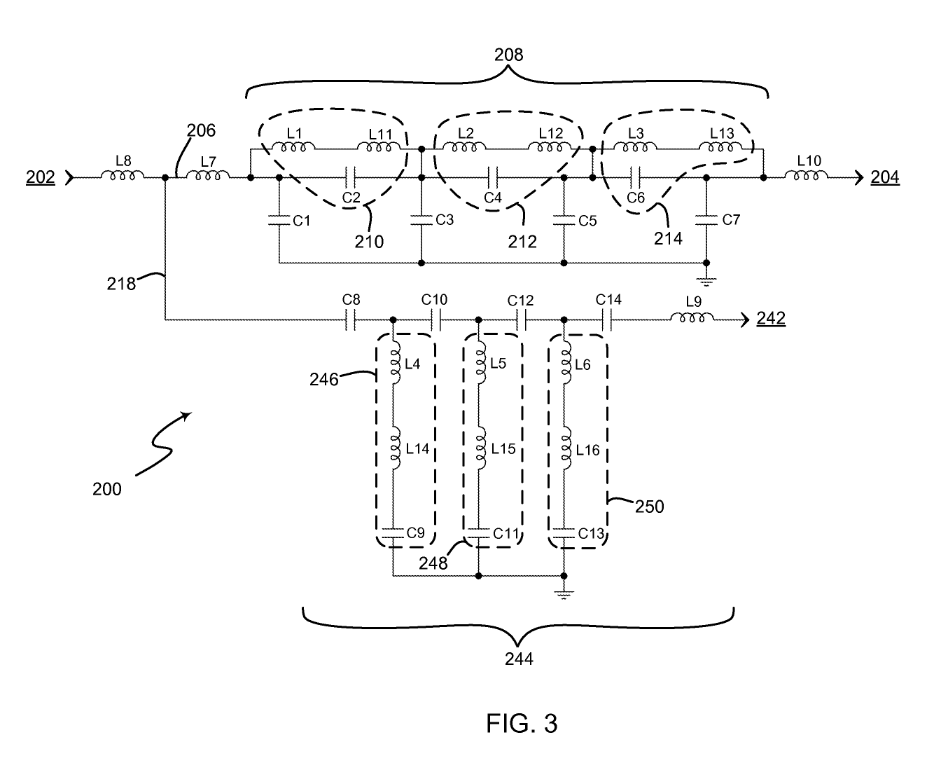

Referring to FIG. 3, the circuit diagram represents the components of an exemplary diplexer filter circuit 200, and the electrical connections among the components. The filter circuit 200 includes an input 202, a first output 204, and a second output 242. A first signal path 206 is defined between the input 202 and the first output 204 and is best characterized as a low pass circuit 208. The low pass circuit 208 includes multiple resonant circuit elements 210, 212, and 214, which are in ordered series electrical communication with each other. Each particular resonant circuit element includes a particular capacitor (C) and at least two series-connected inductors (L) connected in parallel electrical communication with the capacitor. For example, the resonant circuit element 210 includes the series-connected inductors L1 and L11 in parallel communication with the capacitor C2, the resonant circuit element 212 includes the series-connected inductors L2 and L12 in parallel communication with the capacitor C4, and so forth. The resonant circuit elements together with shunt capacitors C1, C3, C5, and C7 form a minimum inductance elliptic function filter. In one embodiment, the low pass circuit 208 is arranged and configured to pass the upstream CATV bandwidth in the 5-50 MHz frequency range and attenuate bandwidth in the 54-1000 MHz frequency range.

A second signal path 218 is defined between the input 202 and the second output 242, and is best characterized as a high pass circuit 244. In the disclosed embodiment of the invention, the high pass circuit 244 includes three shunt elements. The first shunt element 246 is formed by inductors L4 and L14 in series electrical communication with capacitor C9, the second shunt element 248 is formed by inductors L5 and L15 in series electrical communication with capacitor C11, and the third shunt element 250 is formed by inductors L6 and L16 in series electrical communication with capacitor C13. Each shunt element is connected directly to ground. The shunt elements are in parallel, separated from each other and from the input 202 and the second output 242 by capacitors C8, C10, C12, and C14. Inductor L7 is useful for smoothing the frequency response transition from downstream bandwidth to the upstream bandwidth, and inductors L8, L9, and L10 are useful for controlling isolation between output ports 204 and 242, as well as controlling return loss. The return loss is the amount of power reflected back to the input. It is generally desirable to minimize this return loss.

In one embodiment, the high pass circuit 244 is arranged and configured to pass the downstream CATV bandwidth in the 54-1000 MHz frequency range and attenuate the upstream bandwidth in the 5-50 MHz frequency range.

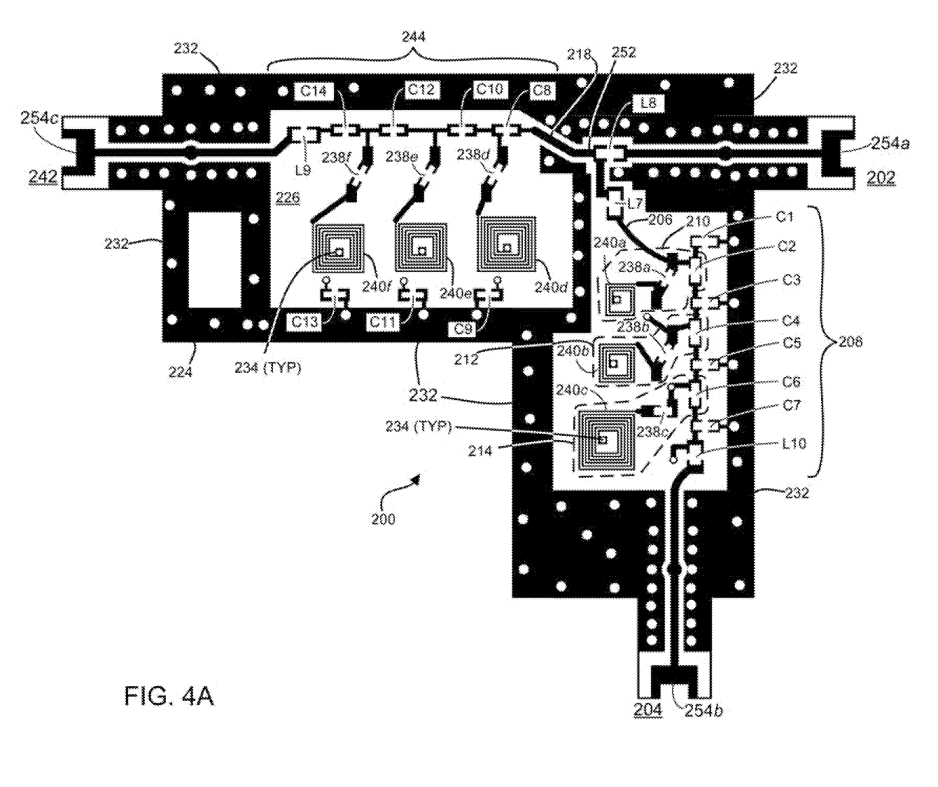

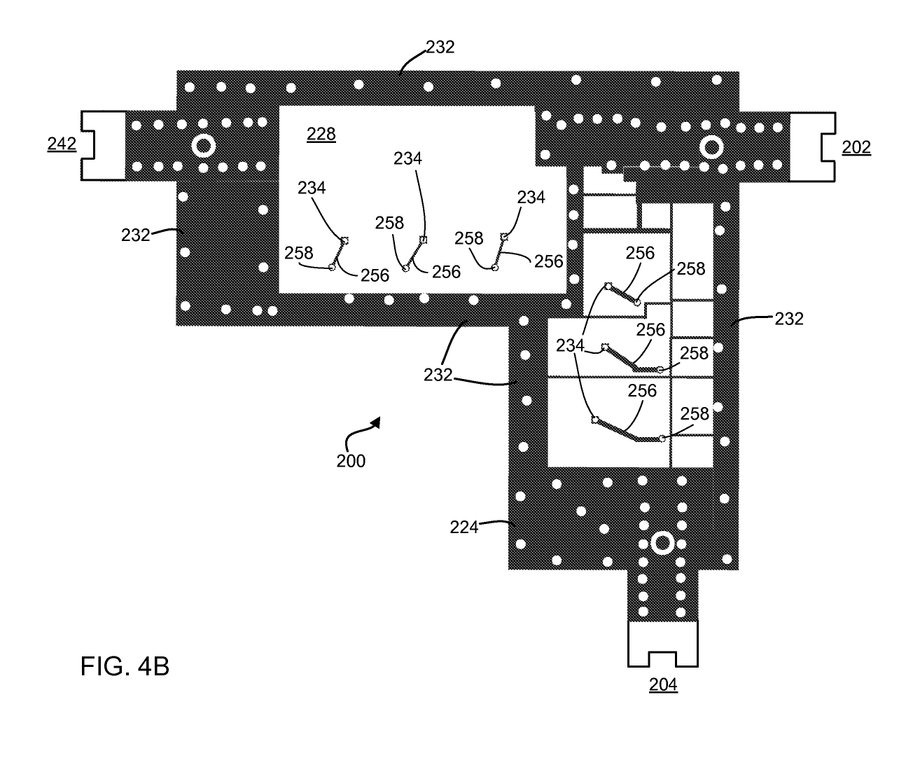

Referring to FIGS. 4A and 4B, shown is a physical layout of the components forming the diplexer filter circuit 200 according to one embodiment of the invention. The filter circuit 200 includes a printed circuit board 224 having a first major surface 226 and a second major surface 228. The first major surface 226 is denoted as the top layer in FIG. 4A, and the second major surface 228 is denoted as the bottom layer in FIG. 4B. The first major surface 226 includes the input 202 and the outputs 204, 242 provided at opposing ends of the circuit board 224 and extending along the signal paths 206 and 218, respectively. The signal path divides at a first junction 252 into path 206 extending along the low pass circuit 208 to the output 204, and into path 218 extending along the high pass circuit 244 to the second output 242. In the illustrated example, the signal paths 206 and 218 are printed on the circuit board 224 using metallization and/or a etching process.

The first major surface 226 further may include a conductive grounding path 232 extending about the periphery of the circuit board 224. In one embodiment, the grounding path 232 is in electrical communication with a coaxial cable connector body (not shown). The connector body, in turn, is in electrical communication with the outer conductive layer of a coaxial cable, which is in electrical communication with the ground block.

The components forming the low pass circuit 208, namely, resonant circuit elements 210, 212, and 214 are shown together with the conductive signal path 206 connecting the components to one another and to the grounding path 232. Shunt capacitor elements C1, C3, C5, and C7 bridge the signal path 206 to the grounding path 232.

The inductor portion of the resonant circuit elements 210, 212, and 214 include coil wound inductor elements 238a-238c (L1, L2, L3 from FIG. 3) in serial electrical communication with etched inductor elements 240a-240c (L11, L12, L13), respectively. The illustrated etched inductor elements 240a-240c are spiral in shape, terminating at a conductive via 234 located at the spiral's center. The coil wound inductor elements 238a-238c and the etched inductor elements 240a-240c are connected in parallel electrical communication with capacitors C2, C4, and C6 respectively. As described above, the combination of coil wound and etched elements provides a small form factor and accurate tuning capability heretofore unrealized in a band pass filter.

The components forming the high pass circuit 244 are shown together with the conductive signal path 218 connecting the components to one another and to the grounding path 232. Specifically, inductors 238d and 240d (L4 and L14 from FIG. 3) are in series electrical communication with capacitor C9, inductors 238e and 240e (L5 and L15) are in series electrical communication with capacitor C11, and inductors 238f and 240f (L6 and L16) are in series electrical communication with capacitor C13. Shunt capacitor elements C9, C11, and C13 bridge the signal path 218 to the grounding path 232, while capacitors C8, C10, C12, and C14 provide dampening to the resonant shunt elements. Also shown in FIG. 4A are conducting pads 254a, 254b, and 254c for connection to the circuit of the usual male and female connectors (not shown).

In the disclosed embodiment, the etched inductor elements 240 are spiral-shaped, meaning a spiral inductor shape that is generally round, such as a circle, a rounded rectangle, an ellipse, a volute, and other generally circular forms. An exemplary spiral etched inductor element 240 may include a spiral conductive trace etched into the printed circuit board 224. Each trace may be monolithically deposited within the printed circuit board 224 by any common printed circuit board processing technique. For example, the trace may be photo-etched into the printed circuit board 224. Photo-etching provides the capability to produce a trace having a narrow width and small separation between traces. The trace spirals inward and terminates at a conductive via 234 that extends through the circuit board substrate.

Turning now to FIG. 4B, the second major surface 228 of the filter circuit 200 includes the grounding path 232 extending about the periphery of the circuit board 224. The vias 234 extending through the circuit board substrate from the etched inductor elements 240 connect to conductive traces 256 that are in turn connected to a second plurality of vias 258 that extend back through the circuit board substrate to connect with the signal path 206. 218 on the first major surface 226.

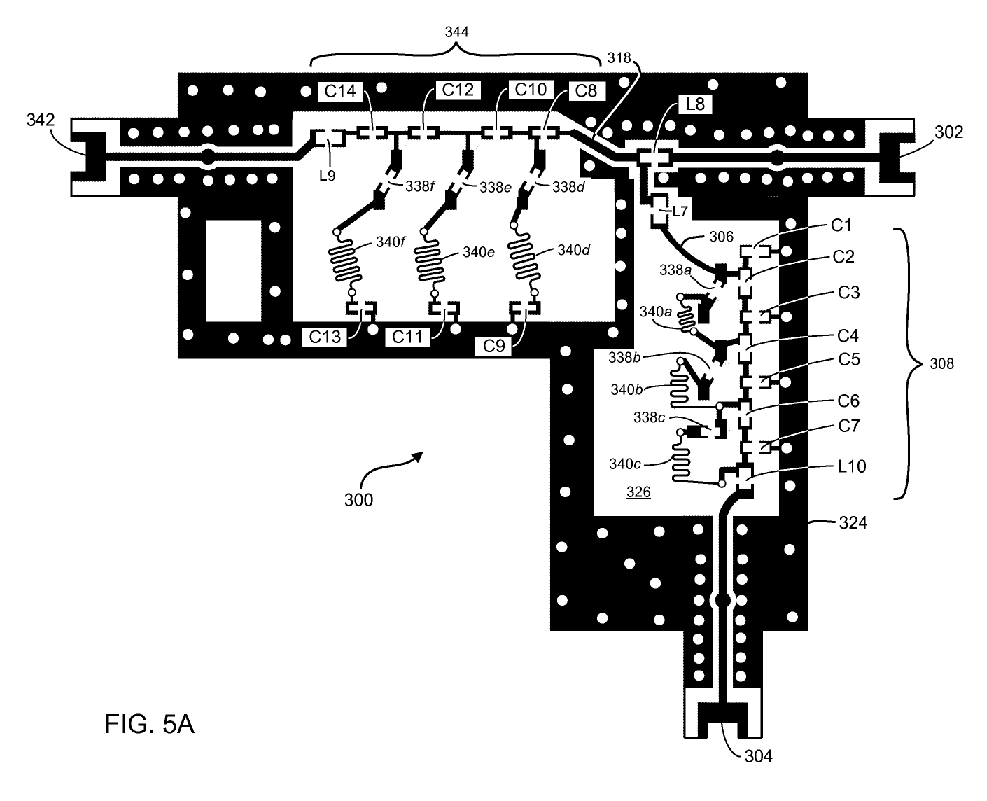

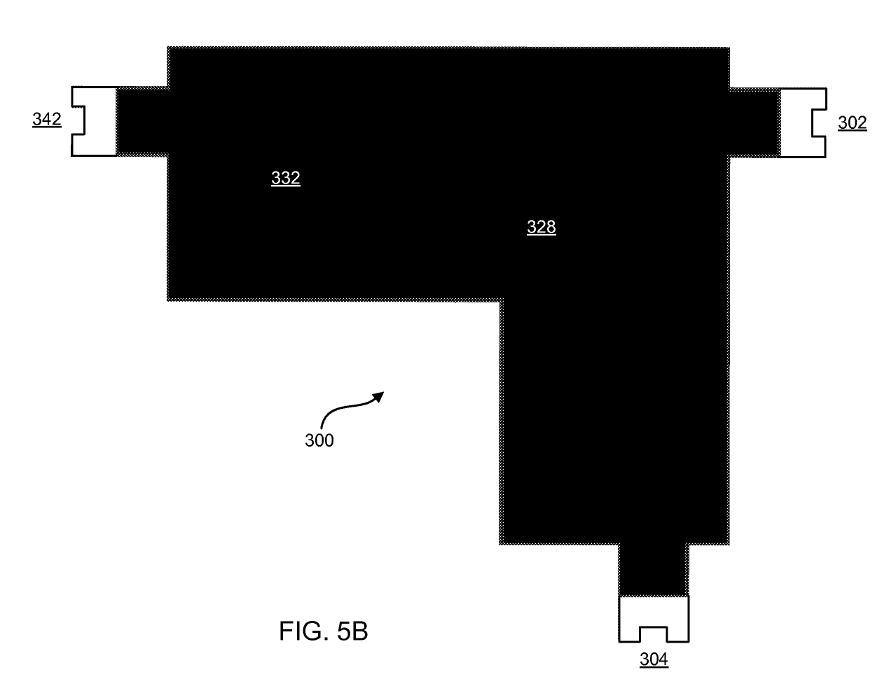

Some filter designs require a solid ground plane on one side of the circuit board. That is, there are to be no penetrating holes through the substrate material for connecting components, and no components are connected, fastened, or otherwise attached to the second side. An example of a solid ground plane is illustrated in FIGS. 5A and 5B, in which a filter circuit 300 includes an input 302, a first output 304, and a second output 342. A first signal path 306 is defined between the input 302 and the output 304 and is best characterized as a low pass circuit 308. A second signal path 318 is defined between the input 302 and the second output 342, and is best characterized as a high pass circuit 344. Note in FIG. 5B that a grounding path 332 is solid across the entire surface (e.g., ground plane). In this example, use of conventional through-hole inductors is not permitted, as they would penetrate the ground plane on the reverse side. However, surface mount designs (SMD) for the components on the first major surface 326 would be acceptable. Surface mount inductors typically include conductive lands on the bottom of the device that bond to conductive pads on the circuit board substrate. The bonding may be accomplished by reflow soldering, for example.

As exemplified in FIG. 5B, a coil wound inductor element 338a-338f may include the surface mount variety, and an etched inductor element 340a-340f must be arranged in geometries other than spiral so the inductor leads do not penetrate the circuit board 324. In the illustrated example, the geometry of the etched inductor element 340 may be formed in a successive “U” pattern. In another example (not shown), the inductor geometry may be formed in a straight line such as a quarter wavelength element or a multiple of a quarter wavelength element, as long as the length of the etched inductor element 340 is sufficient to provide the resonant characteristics.

The disclosed filter circuit 300 allows for precision tuning while maintaining a small form factor and very low manufacturing cost. In addition, the coil wound inductor in series with the etched inductor provides a higher quality factor (Q) than a single etched inductor element, which is desirable.

While the present invention has been particularly shown and described with reference to certain exemplary embodiments, it will be understood by one skilled in the art that various changes in detail may be effected therein without departing from the spirit and scope of the invention as defined by claims that can be supported by the written description and drawings. Further, where exemplary embodiments are described with reference to a certain number of elements it will be understood that the exemplary embodiments can be practiced utilizing either less than or more than the certain number of elements.

I claim:

1. A filter circuit device comprising:
a printed circuit board having first and second opposed major surfaces and first and second opposing sides, the opposed major surfaces being substantially parallel to a single plane and being bisected by a longitudinal axis, the first and second opposing sides being substantially parallel to the longitudinal axis;
an input connected to the printed circuit board, the input having an axis extending substantially parallel to the longitudinal axis;
a output connected to the printed circuit board, the output having an axis extending substantially parallel to the longitudinal axis;
a first signal path disposed on the printed circuit board extending from the input toward the output;
a resonant circuit element coupled to the first signal path and configured as a filter circuit, the resonant circuit element comprising a coil-wound tunable inductor element in serial electrical communication with an etched inductor element, the coil-wound tunable inductor element and the etched inductor element in parallel electrical communication with a capacitor;
a second signal path disposed on the printed circuit board extending from a first node on the first signal path; and
a shunt element disposed on the second signal path, the shunt element comprising a conductive grounding path terminated to electrical ground, and an inductor and a capacitor in series electrical communication coupled to the grounding path.

2. The filter circuit device of claim 1, wherein the shunt element comprises a coil-wound tunable inductor element in serial electrical communication with an etched inductor element, the coil-wound tunable inductor element and the etched inductor element in serial electrical communication with the capacitor.

3. The filter circuit device of claim 1, wherein the first signal path is a low pass filter circuit, and the first signal path further includes a shunt capacitor coupled to electrical ground.

4. The filter circuit device of claim 3, further including a plurality of resonant circuit elements and a plurality of shunt capacitors.

5. The filter circuit device of claim 4, wherein the plurality of resonant circuit elements and a plurality of shunt capacitors are arranged and configured to pass an upstream bandwidth in the 5-50 MHz frequency range.

6. The filter circuit device of claim 1, further comprising a second output connected to the printed circuit board, the second signal path extending from the first node to the second output, the shunt element extending from the second signal path.

7. The filter circuit device of claim 6, further comprising a plurality of shunt elements extending from the second signal path, the shunt elements being arranged in parallel electrical communication and separated from each other by capacitors coupled to the second signal path.

8. The filter circuit device of claim 8, wherein the plurality of shunt elements and capacitors form a high pass filter circuit arranged and configured to pass a downstream CATV bandwidth in the 54-1000 MHz frequency range and attenuate an upstream bandwidth in the 5-50 MHz frequency range.

9. The filter circuit device of claim 1, wherein the second major surface comprises a solid ground plane.

10. The filter circuit device of claim 9, wherein the coil-wound tunable inductor element comprises a surface mount design.

11. The filter circuit device of claim 9, wherein the etched inductor element is a U-shaped design.

12. The filter circuit device of claim 9, wherein the etched inductor element is a quarter wavelength element.

13. The filter circuit device of claim 9, wherein the etched inductor element is a multiple of a quarter wavelength element.

14. The circuit device of claim 1, wherein the etched inductor element is spiral-shaped.

15. A method for tuning a filter circuit, comprising the steps of:
providing on a circuit board an input, an output, a signal path extending from the input toward the output;
providing a shunt element on a second signal path, the second signal path extending from a first node on the first signal path, the shunt element comprising a capacitor coupled to ground;
electrically coupling a resonant circuit element to the first signal path between the first node and the output, the resonant circuit element comprising a tunable coil wound inductor element in serial electrical communication with an etched inductor element, the resonant circuit element further comprising a capacitor in parallel electrical communication to the coil-wound tunable inductor element and the etched inductor element; and
adjusting a resonant frequency of the filter circuit using the coil wound inductor element on the first signal path.

16. The method of claim 15, wherein the step of electrically coupling a resonant circuit element to the first signal path comprises coupling a plurality of resonant circuit elements.

17. The method of claim 16, wherein the filter circuit comprises a minimum inductance elliptic filter.

18. The method of claim 15, the filter circuit further comprising a second output on the second signal path, the second signal path further comprising a plurality of shunt elements, the shunt elements comprising a coil-wound tunable inductor element, an etched inductor element, and a capacitor in serial electrical communication, the filter circuit further comprising a capacitor disposed between the plurality of shunt elements, the method further comprising the step of adjusting a resonant frequency of the filter circuit using the coil wound inductor element on the second signal path.

19. The method of claim 15, wherein the filter circuit is a band pass filter circuit, the step of adjusting a resonant frequency on the first signal path comprises tuning the coil wound inductor element to pass a downstream cable television bandwidth in the 54-1000 MHz frequency range and attenuate the upstream bandwidth in the 5-50 MHz frequency range.

20. The method of claim 19, wherein the step of adjusting a resonant frequency on the second signal path comprises tuning the coil wound inductor element to pass a downstream cable television bandwidth in the 5-50 MHz frequency range and attenuate bandwidth in the 54-1000 MHz frequency range.
